(19) United States
(12) Patent Application Publication
(10) Pub. No.: US 2025/0061255 A1
(43) Pub. Date: Feb. 20, 2025

(54) Predicting Estimated Ultimate Recovery By Well In Unconventional Reservoirs From Reservoir Rock & Fluid, Wellbore Geometry, And Completion Properties

(71) Applicant: Landmark Graphics Corporation, Houston, TX (US)

(72) Inventor: Benjamin Freestone, Houston, TX (US)

(73) Assignee: Landmark Graphics Corporation, Houston, TX (US)

(21) Appl. No.: 18/759,280

(22) Filed: Jun. 28, 2024

Related U.S. Application Data
(60) Provisional application No. 63/519,984, filed on Aug. 16, 2023.

(51) Int. Cl. G06F 30/28; E21B 49/00

(52) U.S. Cl. CPC G06F 30/28; E21B 49/00; E21B 2200/20; E21B 2200/22

(57) ABSTRACT

A method for analyzing an unproduced reservoir that includes obtaining a new reservoir dataset, for the unproduced reservoir, that includes a plurality of desired reservoir data types, identifying a plurality of existing reservoir datasets, in a historical reservoir database, where each reservoir dataset, of the plurality of existing reservoir datasets, includes a desired reservoir data type of the plurality of desired reservoir data types, training a plurality of finalist machine learning models using the plurality of existing reservoir datasets, identifying a best finalist machine learning model of the plurality of finalist machine learning models, and processing the new reservoir dataset, using best finalist machine learning model, to generate analysis data for the unproduced reservoir.

### BACKGROUND

The oil and gas industry may use wellbores as fluid conduits to access subterranean deposits of various fluids and minerals which may include hydrocarbons. A drilling operation may be utilized to construct the fluid conduits which are capable of producing hydrocarbons disposed in subterranean formations. Wellbores may be constructed, in increments, as tapered sections, which sequentially extend into a subterranean formation.

### BRIEF DESCRIPTION OF DRAWINGS

These drawings illustrate certain aspects of some examples of the present disclosure and should not be used to limit or define the disclosure.

FIG. 1A is a diagram of an example drilling environment.

FIG. 1B is a diagram of an example wireline environment.

FIG. 2 is a diagram of an example computing environment.

FIG. 3A is a diagram of an architecture for training a machine learning model.

FIG. 3B is a diagram of a process for training a machine learning model.

FIG. 4A is a diagram of an artificial neural network.

FIG. 4B is a diagram of an artificial neuron.

FIG. 5A is a diagram of a historical borehole database and corresponding reservoir datasets.

FIG. 5B is a diagram of a reservoir dataset and corresponding reservoir data types.

FIG. 6A is a flowchart of a method for preparing datasets.

FIG. 6B is a flowchart of a method for training machine learning models.

FIG. 6C is a flowchart of a method for generating and using analysis data of a machine learning model.

### DETAILED DESCRIPTION

### Overview and Advantages

In general, this application discloses one or more embodiments of methods and systems for predicting estimated ultimate recovery (EUR) from a subterranean reservoir using machine learning techniques. Specifically, as discussed in one or more embodiments herein, existing data from previous wells is utilized to train machine learning models (in a broader deep learning structured regression model) to predict the EUR of a formation earlier in the planning and drilling process.

Generally, in the oil and gas industry, there is a search for product (oil and/or gas in subterranean reservoirs) and delivery of that product to market (extraction and processing of the oil and/or gas). Part of the process of planning for the extraction of resources from a reservoir (and for determining the owner's valuation) is calculating EUR for any given reservoir. For traditional reservoirs, with familiar geometry and low complexity, EUR may be estimated with higher precision and accuracy. As a non-limiting example, for conventional reservoirs, extraction workflows combine mass and volume of the reservoir rock and fluid properties (a static model) with production (a dynamic model) to predict well performance.

However, not all reservoirs are of the same type and complexity. Some reservoirs may be considered “unconventional” due to their resource type and more complicated geometry (e.g., shape, porosity, depth, etc.). EUR is intrinsically linked to the inherent uncertainty of the characteristics of the reservoir rock and fluid. That is, due to the complexity of the porous media and the fluids contained within unconventional wells, the physics defining the production are not well delineated and EUR cannot be easily estimated. Consequently, empiricism is used for the analysis of unconventional reservoirs (e.g., the use of existing data for reservoirs sharing some properties, with known EUR)—as opposed to a physics-based, first principles analysis used for conventional reservoirs.

Yet, for manual empirical approaches, there is an inherent lack of data for “unconventional” reservoirs (if such reservoirs were more common, they would not be “unconventional”). Further, even as new data is collected for unconventional reservoirs, lack of automation in the process hampers incorporation of such newly available data. Typically, EUR for unconventional reservoirs has relied on “offset analysis” combined with expert analysis to predict new well delivery producing type-curves. The reliance on decline curve analysis makes information on reservoir quality and completion efficacy difficult to incorporate. Further, as planning of a proposed well progresses, EUR becomes a dynamic target, further obfuscating prediction quality prior to commencing drilling.

Accordingly, as disclosed in one or more embodiments herein, machine learning regression algorithms provide methods to predict EUR with increased accuracy, precision, and robustness. Specifically, given sufficient computing power and sufficient historical data of reservoirs with overlapping properties, the inherent complexity of unconventional reservoirs may be accounted for, without time consuming and bespoke modeling (likely not useful for other reservoirs). Such modeling may be automated and include, as a preliminary or intermediary step, training machine learning models to identify and account for relevant variables (e.g., identifying the properties of greatest criticality to prediction). Thus, such machine learning processes may be automated, identify relevant properties, and provide more consistent, accurate, and precise predictions of EUR.

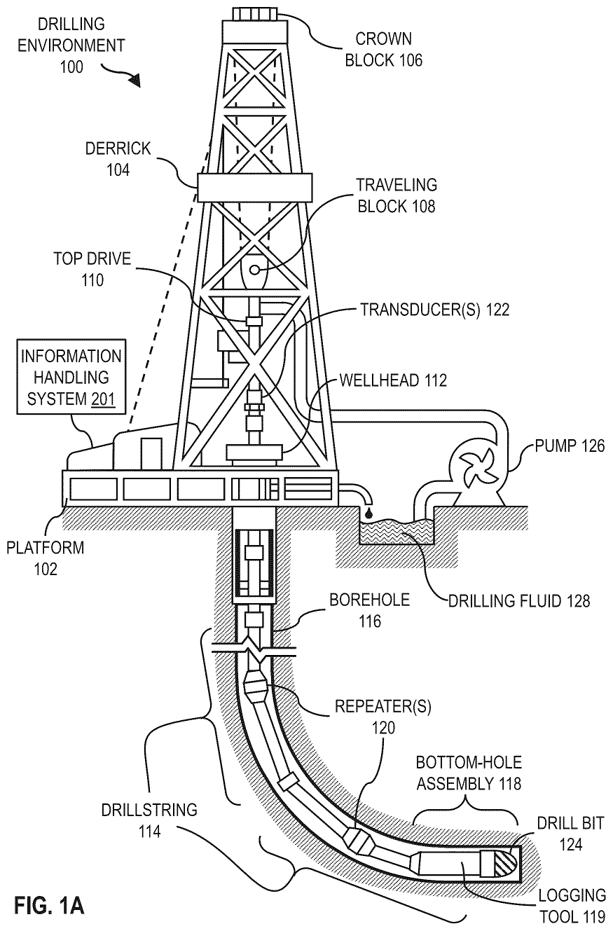

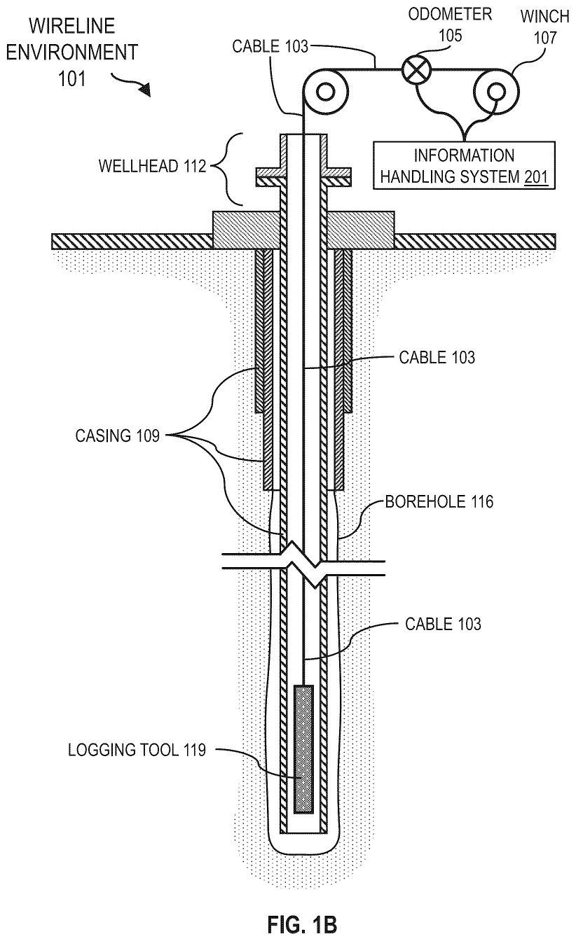

### —FIG. 1A—

FIG. 1A is a diagram of an example drilling environment. Drilling environment 100 may include platform 102 that supports derrick 104 having traveling block 108 for raising and lowering top drive 110 and drillstring 114. Top drive 110 supports and rotates drillstring 114 as it is lowered through wellhead 112. In turn, drill bit 124, located at the end of drillstring 114, may create borehole 116. Each of these components is described below.

Platform 102 is a structure which may be used to support one or more other components of drilling environment 100 (e.g., derrick 104). Platform 102 may be designed and constructed from suitable materials (e.g., concrete) which are able to withstand the forces applied by other components (e.g., the weight and counterforces experienced by derrick 104). In any embodiment, platform 102 may be constructed to provide a uniform surface for drilling operations in drilling environment 100.

Derrick 104 is a structure which may support, contain, and/or otherwise facilitate the operation of one or more pieces of the drilling equipment. In any embodiment, derrick 104 may provide support for crown block 106, traveling block 108, and/or any part connected to (and including) drillstring 114. Derrick 104 may be constructed from any suitable materials (e.g., steel) to provide the strength necessary to support those components.

Crown block 106 is one or more simple machine(s) which may be rigidly affixed to derrick 104 and include a set of pulleys (e.g., a “block”), threaded (e.g., “reeved”) with a drilling line (e.g., a steel cable), to provide mechanical advantage. Crown block 106 may be disposed vertically above traveling block 108, where traveling block 108 is threaded with the same drilling line.

Traveling block 108 is one or more simple machine(s) which may be movably affixed to derrick 104 and include a set of pulleys, threaded with a drilling line, to provide mechanical advantage. Traveling block 108 may be disposed vertically below crown block 106, where crown block 106 is threaded with the same drilling line. In any embodiment, traveling block 108 may be mechanically coupled to drillstring 114 (e.g., via top drive 110) and allow for drillstring 114 (and/or any component thereof) to be lifted from (and out of) borehole 116. Both crown block 106 and traveling block 108 may use a series of parallel pulleys (e.g., in a “block and tackle” arrangement) to achieve significant mechanical advantage, allowing for the drillstring to handle greater loads (compared to a configuration that uses non-parallel tension). Traveling block 108 may move vertically (e.g., up, down) within derrick 104 via the extension and retraction of the drilling line.

Top drive 110 is a machine which may be configured to rotate drillstring 114. Top drive 110 may be affixed to traveling block 108 and configured to move vertically within derrick 104 (e.g., along with traveling block 108). In any embodiment, the rotation of drillstring 114 (caused by top drive 110) may allow for drillstring 114 to carve borehole 116. Top drive 110 may use one or more motor(s) and gearing mechanism(s) to cause rotations of drillstring 114. In any embodiment, a rotatory table (not shown) and a “Kelly” drive (not shown) may be used in addition to, or instead of, top drive 110.

Wellhead 112 is a machine which may include one or more pipes, caps, and/or valves to provide pressure control for contents within borehole 116 (e.g., when fluidly connected to a well (not shown)). In any embodiment, during drilling, wellhead 112 may be equipped with a blowout preventer (not shown) to prevent the flow of higher-pressure fluids (in borehole 116) from escaping to the surface in an uncontrolled manner. Wellhead 112 may be equipped with other ports and/or sensors to monitor pressures within borehole 116 and/or otherwise facilitate drilling operations.

Drillstring 114 is a machine which may be used to carve borehole 116 and/or gather data from borehole 116 and the surrounding geology. Drillstring 114 may include one or more drillpipe(s), one or more repeater(s) 120, and bottom-hole assembly 118. Drillstring 114 may rotate (e.g., via top drive 110) to form and deepen borehole 116 (e.g., via drill bit 124) and/or via one or more motor(s) attached to drillstring 114.

Borehole 116 is a hole in the ground which may be formed by drillstring 114 (and one or more components thereof). Borehole 116 may be partially or fully lined with casing to protect the surrounding ground from the contents of borehole 116, and conversely, to protect borehole 116 from the surrounding ground.

Bottom-hole assembly 118 is a machine which may be equipped with one or more tools for creating, providing structure, and maintaining borehole 116, as well as one or more tools for measuring the surrounding environment (e.g., measurement while drilling (MWD), logging while drilling (LWD) via logging tool 119). In any embodiment, bottom-hole assembly 118 may be disposed at (or near) the end of drillstring 114 (e.g., in the most “downhole” portion of borehole 116).

Non-limiting examples of tools that may be included in bottom-hole assembly 118 include a drill bit (e.g., drill bit 124), casing tools (e.g., a shifting tool), a plugging tool, a mud motor, a drill collar (thick-walled steel pipes that provide weight and rigidity to aid the drilling process), actuators (and pistons attached thereto), a steering system, and any measurement tool (e.g., logging tool 119, sensors, probes, particle generators, etc.).

Further, bottom-hole assembly 118 may include a telemetry sub to maintain a communications link with the surface (e.g., with information handling system 201). Such telemetry communications may be used for (i) transferring tool measurement data from bottom-hole assembly 118 to surface receivers, and/or (ii) receiving commands (from the surface) to bottom-hole assembly 118 (e.g., for use of one or more tool(s) in bottom-hole assembly 118).

Non-limiting examples of techniques for transferring tool measurement data (to the surface) include mud pulse telemetry and through-wall acoustic signaling. For through-wall acoustic signaling, one or more repeater(s) 120 may detect, amplify, and re-transmit signals from bottom-hole assembly 118 to the surface (e.g., to information handling system 201), and conversely, from the surface (e.g., from information handling system 201) to bottom-hole assembly 118.

Logging tool 119 is a device which may be used to measure one or more properties of borehole 116 or the surrounding ground (e.g., and a reservoir therein). Logging tool 119 may include any combination of sensors, probes, and particle generators. Non-limiting examples of types of logging (which may be performed by logging tool 119) include video logging (e.g., to provide visual data), resistivity logging (e.g., to identify hydrocarbons in a reservoir), gamma radiation logging, electromagnetic induction logging, casing deviation logging, temperature logging, pressure logging, and/or any other type of sensor, measurement device, or combination thereof.

Repeater 120 is a device which may be used to receive and send signals from one component of drilling environment 100 to another component of drilling environment 100. As a non-limiting example, repeater 120 may be used to receive a signal from a tool on bottom-hole assembly 118 and send that signal to information handling system 201. Two or more repeaters 120 may be used together, in series, such that a signal to/from bottom-hole assembly 118 may be relayed through two or more repeaters 120 before reaching its destination.

Transducer 122 is a device which may be configured to convert non-digital data (e.g., vibrations, other analog data) into a digital form suitable for information handling system 201. As a non-limiting example, one or more transducer(s) 122 may convert signals between mechanical and electrical forms, enabling information handling system 201 to receive the signals from a telemetry sub, on bottom-hole assembly 118, and conversely, transmit a downlink signal to the telemetry sub on bottom-hole assembly 118. In any embodiment, transducer 122 may be located at the surface and/or any part of drillstring 114 (e.g., as part of bottom-hole assembly 118).

Drill bit 124 is a machine which may be used to cut through, scrape, and/or crush (i.e., break apart) materials in the ground (e.g., rocks, dirt, clay, etc.). Drill bit 124 may be disposed at the frontmost point of drillstring 114 and bottom-hole assembly 118. In any embodiment, drill bit 124 may include one or more cutting edges (e.g., hardened metal points, surfaces, blades, protrusions, etc.) to form a geometry which aids in breaking ground materials loose and further crushing that material into smaller sizes. In any embodiment, drill bit 124 may be rotated and forced into (i.e., pushed against) the ground material to cause the cutting, scraping, and crushing action. The rotations of drill bit 124 may be caused by top drive 110 and/or one or more motor(s) located on drillstring 114 (e.g., on bottom-hole assembly 118).

Pump 126 is a machine that may be used to circulate drilling fluid 128 from a reservoir, through a feed pipe, to derrick 104, to the interior of drillstring 114, out through drill bit 124 (through orifices, not shown), back upward through borehole 116 (around drillstring 114), and back into the reservoir. In any embodiment, any appropriate pump 126 may be used (e.g., centrifugal, gear, etc.) which is powered by any suitable means (e.g., electricity, combustible fuel, etc.).

Drilling fluid 128 is a liquid which may be pumped through drillstring 114 and borehole 116 to collect drill cuttings, debris, and/or other ground material from the end of borehole 116 (e.g., the volume most recently hollowed by drill bit 124). Further, drilling fluid 128 may provide conductive cooling to drill bit 124 (and/or bottom-hole assembly 118). In any embodiment, drilling fluid 128 may be circulated via pump 126 and filtered to remove unwanted debris.

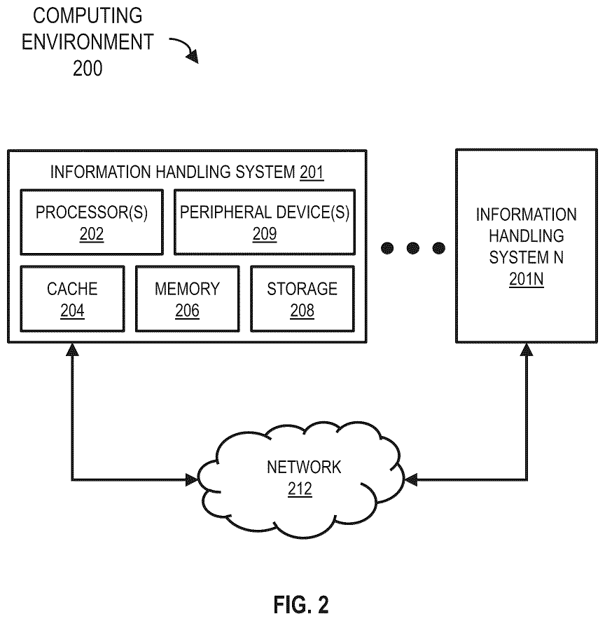

Information handling system 201 is a hardware computing system which may be operatively connected to drillstring 114 (and/or other various components of the drilling environment). In any embodiment, information handling system 201 may utilize any suitable form of wired and/or wireless communication to send and/or receive data to and/or from other components of drilling environment 100. In any embodiment, information handling system 201 may receive a digital telemetry signal, demodulate the signal, display data (e.g., via a visual output device), and/or store the data. In any embodiment, information handling system 201 may send a signal (with data) to one or more components of drilling environment 100 (e.g., to control one or more tools on bottom-hole assembly 118). Additional details regarding information handling system 201 are in the description for FIG. 2.

### —FIG. 1B—

FIG. 1B is a diagram of an example wireline environment. Wireline environment 101 may include logging tool 119 disposed at the end of cable 103 and placed into borehole 116 by winch 107 using one or more pulley(s). Components not previously discussed are described below.

Cable 103 is an elongated structure which may be used for retrievably transporting one or more tool(s) (e.g., logging tool 119) and facilitating communication with those tool(s). Cable 103 may be one or more strand(s) of material used to provide tensile strength. In one or more embodiments, when cable 103 is constructed from two or more strands, the strands may be twisted and/or braided to form a rope. Strands may be constructed from any suitable material to provide sufficient tensile strength (e.g., iron, steel, any metal alloy, etc.). In any embodiment, cable 103 may be coated (e.g., with plastic) to protect the cable material from corrosion and/or rust. In any embodiment, distal ends of cable 103 may be terminated with Flemish eyes, turnback eyes, swages, clips, and/or any other mechanism to allow for the attachment of another device (e.g., winch 107, logging tool 119). Further, cable 103 may be constructed with one or more wire(s) (e.g., conductive metal, fiber optic strands, etc.) to allow for data transmission with tool(s) disposed at the end of cable 103.

Odometer 105 is a device which may be used to measure, track, and/or record the movement and/or relative displacement of cable 103. In one or more embodiments, odometer 105 uses one or more mechanical and/or electrical component(s) to measure the extension and retraction of cable 103 and thereby the location of any device affixed to cable 103 (e.g., the position of logging tool 119 within borehole 116). In one or more embodiments, odometer 105 may be operatively connected to information handling system 201, where data from odometer 105 is received, stored, processed, analyzed, and/or used in one or more processes (e.g., software to control the location of logging tool 119, software to control the speed at which cable 103 moves via winch 107, etc.).

Winch 107 is a device which may be used to control the position, movement, speed, and/or direction of cable 103. Winch 107 may include a motor, gearbox, spool, brake, and/or controller. As a non-limiting example, a controller of winch 107 may operatively connect with information handling system 201. In turn, information handling system 201 may send one or more command(s) to the controller to cause the motor to unwind cable 103 from a spool (e.g., via a gearbox). In turn, cable 103 may be extended and lowered into borehole 116. Conversely, as a non-limiting example, information handling system 201 may send one or more command(s) to the controller to cause the motor (of winch 107) to wind cable 103 onto the spool. In turn, cable 103 may be retracted and pulled upward with respect to borehole 116. Further, winch 107 may be used to hold cable 103 in a static position (braking, not extending or retracting) allowing any component affixed to cable 103 (e.g., logging tool 119) to remain stationary.

Casing 109 is concrete and/or metal lining that separates the hollow interior of borehole 116 from the surrounding ground. Casing 109 may be used to protect the surrounding ground from the contents disposed in the hollow interior of casing 109, and conversely, to protect the contents of the hollow interior of casing 109 from the surrounding ground.

### —FIG. 2—

FIG. 2 is a diagram of an example computing environment. Computing environment 200 may include one or more information handling system(s) 201 connected via network 212. Each of these components is described below.

Information handling system 201 is a hardware computing device which may be utilized to perform various steps, methods, and techniques disclosed herein (e.g., via the execution of software). In any embodiment, information handling system 201 may include one or more processor(s) 202, cache 204, memory 206, storage 208, and/or one or more peripheral device(s) 209. Any two or more of these components may be operatively connected via a system bus (not shown) that provides a means for transferring data between those components. Although each component is depicted and disclosed as individual functional components, these individual components may be combined (or divided) into any combination or configuration of components.

A system bus is a system of hardware connections (e.g., sockets, ports, wiring, conductive tracings on a printed circuit board (PCB), etc.) used for sending (and receiving) data to (and from) each of the components connected thereto. In any embodiment, a system bus allows for communication via an interface and protocol (e.g., inter-integrated circuit (I2C), peripheral component interconnect (express) (PCI (c)) fabric, etc.) that may be commonly recognized by the components utilizing the system bus. In any embodiment, a basic input/output system (BIOS) may be configured to transfer information between the components using the system bus (e.g., during initialization of information handling system 201).

In any embodiment, information handling system 201 may additionally include internal physical interface(s) (e.g., serial advanced technology attachment (SATA) ports, peripheral component interconnect (PCI) ports, PCI express (PCIe) ports, next generation form factor (NGFF) ports, M.2 ports, etc.) and/or external physical interface(s) (e.g., universal serial bus (USB) ports, recommended standard (RS) serial ports, audio/visual ports, etc.). Internal physical interface(s) and external physical interface(s) may facilitate the operative connection to one or more peripheral device(s) 209.

Non-limiting examples of information handling system 201 include a general purpose computer (e.g., a personal computer, desktop, laptop, tablet, smart phone, etc.), a network device (e.g., switch, router, multi-layer switch, etc.), a server (e.g., a blade-server in a blade-server chassis, a rack server in a rack, etc.), a controller (e.g., a programmable logic controller (PLC)), and/or any other type of computing device with the aforementioned capabilities. Further, information handling system 201 may be operatively connected to another information handling system 201 via network 212 in a distributed computing environment. As used herein, a “computing device” may be equivalent to an information handling system.

Processor 202 is a hardware device which may take the form of an integrated circuit configured to process computer-executable instructions (e.g., software). Processor 202 may execute (e.g., read and process) computer-executable instructions stored in cache 204, memory 206, and/or storage 208. Processor 202 may be a self-contained computing system, including a system bus, memory, cache, and/or any other components of a computing device. Processor 202 may include multiple processors, such as a system having multiple physically separated processors in different sockets, or a system having multiple processor cores on a single physical chip. A multi-core processor may be symmetric or asymmetric. Multiple processors 202, and/or processor cores thereof, may share resources (e.g., cache 204, memory 206) or may operate using independent resources.

Non-limiting examples of processor 202 include general-purpose processor (e.g., a central processing unit (CPU)), an application specific integrated circuit (ASIC), a programmable gate array (PGA), a field programmable gate array (FPGA), a digital signal processor (DSP), and any digital or analog circuit configured to perform operations based on input data (e.g., execute program instructions).

Cache 204 is one or more hardware device(s) capable of storing digital information (e.g., data) in a non-transitory medium. Cache 204 expressly excludes transitory media (e.g., transitory waves, energy, carrier signals, electromagnetic waves, signals per se, etc.). Cache 204 may be considered “high-speed”, having comparatively faster read/write access than memory 206 and storage 208, and therefore utilized by processor 202 to process data more quickly than data stored in memory 206 or storage 208. Accordingly, processor 202 may copy needed data to cache 204 (from memory 206 and/or storage 208) for comparatively speedier access when processing that data. In any embodiment, cache 204 may be included in processor 202 (e.g., as a subcomponent). In any embodiment, cache 204 may be physically independent, but operatively connected to processor 202.

Memory 206 is one or more hardware device(s) capable of storing digital information (e.g., data) in a non-transitory medium. Memory 206 expressly excludes transitory media (e.g., transitory waves, energy, carrier signals, electromagnetic waves, signals per se, etc.). In any embodiment, when accessing memory 206, software (executed via processor 202) may be capable of reading and writing data at the smallest units of data normally accessible (e.g., “bytes”). Specifically, memory 206 may include a unique physical address for each byte stored thereon, thereby enabling the ability to access and manipulate (read and write) data by directing commands to a specific physical address associated with a byte of data (i.e., “random access”). Non-limiting examples of memory 206 devices include flash memory, random access memory (RAM), dynamic RAM (DRAM), static RAM (SRAM), resistive RAM (ReRAM), read-only memory (ROM), and electrically erasable programmable ROM (EEPROM). In any embodiment, memory 206 devices may be volatile or non-volatile.

Storage 208 is one or more hardware device(s) capable of storing digital information (e.g., data) in a non-transitory medium. Storage 208 expressly excludes transitory media (e.g., transitory waves, energy, carrier signals, electromagnetic waves, signals per se, etc.). In any embodiment, the smallest unit of data readable from storage 208 may be a “block” (instead of a “byte”). Prior to reading and/or manipulating the data on storage 208, one or more block(s) may be copied to an intermediary storage medium (e.g., cache 204, memory 206) where the data may then be accessed in “bytes” (e.g., via random access). In any embodiment, data on storage 208 may be accessed in “bytes” (like memory 206). Non-limiting examples of storage 208 include integrated circuit storage devices (e.g., a solid-state drive (SSD), Non-Volatile Memory Express (NVMe), flash memory, etc.), magnetic storage devices (e.g., a hard disk drive (HDD), floppy disk, magnetic tape, diskette, cassettes, etc.), optical media (e.g., a compact disc (CD), digital versatile disc (DVD), etc.), and printed media (e.g., barcode, quick response (QR) code, punch card, etc.).

As used herein, “non-transitory computer readable medium” is cache 204, memory 206, storage 208, and/or any other hardware device capable of non-transitorily storing and/or carrying data.

Peripheral device 209 is a hardware device configured to send (and/or receive) data to (and/or from) information handling system 201 via one or more internal and/or external physical interface(s). Any peripheral device 209 may be categorized as one or more “types” of computing devices (e.g., an “input” device, “output” device, “communication” device, etc.). However, such categories are not comprehensive and are not mutually exclusive. Such categories are listed herein strictly to provide understandable groupings of the potential types of peripheral devices 209. As such, peripheral device 209 may be an input device, an output device, a communication device, and/or any other optional computing component.

An input device is a hardware device that receives data into information handling system 201. In any embodiment, an input device may be a human interface device which facilitates user interaction by collecting data based on user inputs (e.g., a mouse, keyboard, camera, microphone, touchpad, touchscreen, fingerprint reader, joystick, gamepad, etc.). In any embodiment, an input device may collect data based on raw inputs, regardless of human interaction (e.g., any sensor, logging tool, audio/video capture card, etc.). In any embodiment, an input device may be a reader for accessing data on a non-transitory computer readable medium (e.g., a CD drive, floppy disk drive, tape drive, scanner, etc.).

An output device is a hardware device that sends data from information handling system 201. In any embodiment, an output device may be a human interface device which facilitates providing data to a user (e.g., a visual display monitor, speakers, printer, status light, haptic feedback device, etc.). In any embodiment, an output device may be a writer for facilitating storage of data on a non-transitory computer readable medium (e.g., a CD drive, floppy disk drive, magnetic tape drive, printer, etc.).

A communication device is a hardware device capable of sending and/or receiving data with one or more other communication device(s) (e.g., connected to another information handling system 201 via network 212). A communication device may communicate via any suitable form of wired interface (e.g., Ethernet, fiber optic, serial communication etc.) and/or wireless interface (e.g., Wi-Fi® (Institute of Electrical and Electronics Engineers (IEEE) 802.11), Bluetooth® (IEEE 802.15.1), etc.) and utilize one or more protocol(s) for the transmission and receipt of data (e.g., transmission control protocol (TCP), user datagram protocol (UDP), internet protocol (IP), remote direct memory access (RDMA), etc.). Non-limiting examples of a communication device include a network interface card (NIC), a modem, an Ethernet card/adapter, and a Wi-Fi® card/adapter.

An optional computing component is any hardware device that operatively connects to information handling system 201 and extends the capabilities of information handling system 201. Non-limiting examples of an optional computing components include a graphics processing unit (GPU), a data processing unit (DPU), and a docking station.

As used herein, “software” (e.g., “code”, “algorithm”, “application”, “routine”) is data in the form of computer-executable instructions. Processor 202 may execute (e.g., read and process) software to perform one or more function(s). Non-limiting examples of functions may include reading existing data, modifying existing data, generating new data, and using any capability of information handling system 201 (e.g., reading existing data from memory 206, generating new data from the existing data, sending the generated data to a GPU to be displayed on a monitor). Although software physically persists in cache 204, memory 206, and/or storage 208, one or more software instances may be depicted, in the figures, as an external component of any information handling system 201 that interacts with one or more information handling system(s) 201.

Network 212 is a collection of connected information handling systems (e.g., 201, 201N) that allows for the exchange of data and/or the sharing of computing resources therebetween. Non-limiting examples of network 212 include a local area network (LAN), a wide area network (WAN) (e.g., the Internet), a mobile network, any combination thereof, and any other type of network that allows for the communication of data and sharing of resources among computing devices operatively connected thereto. A person of ordinary skill in the relevant art, having the benefit of this detailed description, would appreciate that a network is a collection of operatively connected computing devices that enables communication between those computing devices.

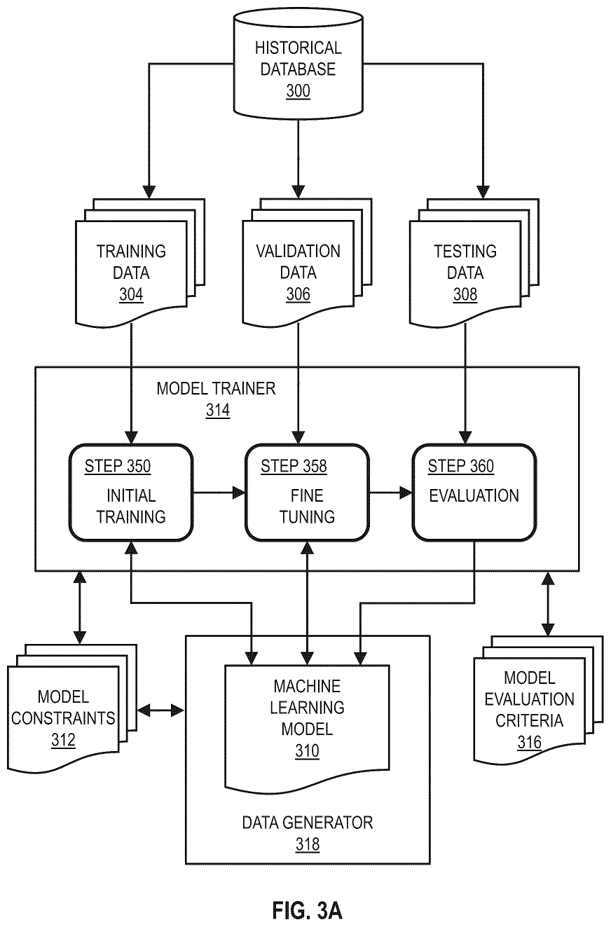

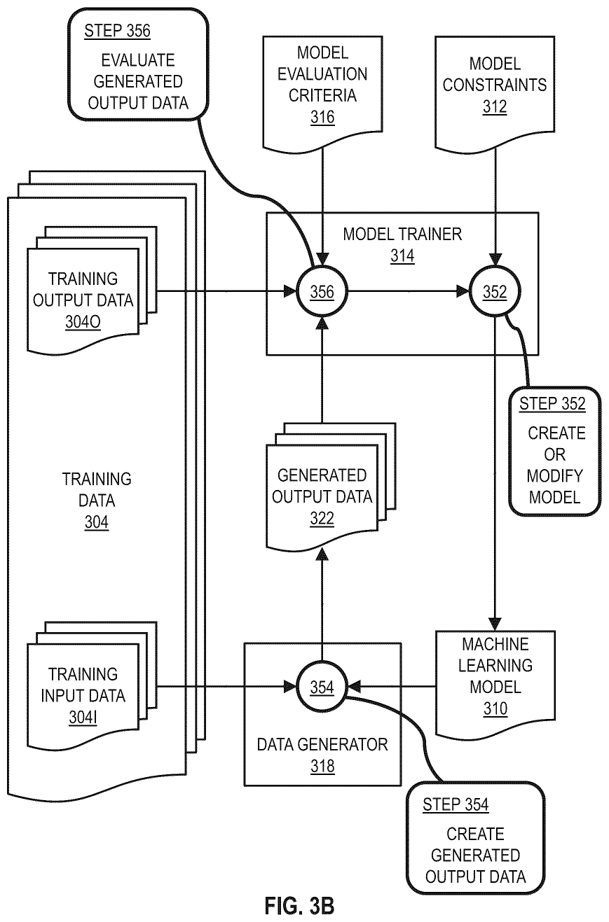

### —FIG. 3A—

FIG. 3A is a diagram of an architecture for training a machine learning model.

Historical database 300 is a data structure which includes one or more subset(s) of data that may be used to train machine learning model 310. In one or more embodiments, historical database 300 may include data of any type (e.g., text, images, spreadsheets, computer aided design (CAD) files, videos, etc.) in any form (e.g., structured, unstructured, sorted, unsorted). Historical database 300 may be stored on one or more information handling system(s) 201 (e.g., within storage 208 and/or memory 206 of a single information handling system 201, or in a virtual storage volume across multiple information handling systems 201).

In one or more embodiments, historical database 300 is a data structure which may store information in relational tuples and attributes. Non-limiting examples of historical database 300 include one or more table(s) each with one or more “row(s)” (e.g., tuple(s)) and “column(s)” (e.g., attribute(s)), a structured file for storing tabular data (e.g., a comma-separated value (CSV) file, a tab-separated value (TSV) file, etc.), a relational database management system (RDBMS) (e.g., using Structured Query Language (SQL)), and/or any other data structure capable of storing data.

One or more portion(s) of historical database 300 may be divided into different categories of data. As a non-limiting example, for the purpose of training a machine learning model 310, historical database 300 may be divided into training data 304, validation data 306, and testing data 308. Consider a scenario where historical database 300 consists of 100,000 image files respectively paired with 100,000 text files, each including a description of each associated image. Of those 100,000 pairs of files, (i) 70,000 may be designated as training data 304, (ii) 20,000 may be designated as validation data 306 (entirely unique from training data 304), and (iii) the remaining 10,000 may be designated as testing data 308 (entirely unique from training data 304 and validation data 306). In such an example, the parsing of the files into various subsets may not be dependent upon any of the data itself but may divide the historical database 300 arbitrarily (or randomly).

Training data 304 is data which may be a subset of historical database 300. In one or more embodiments, training data 304 may be used for initial training (see step 350) of a machine learning model 310. Further, training data 304 may be multiple times larger (i.e., having greater quantities of data) compared to validation data 306 and testing data 308.

Validation data 306 is data which may be a subset of historical database 300. In one or more embodiments, validation data 306 is data that the machine learning model 310 has not previously been provided and/or had access. Thus, validation data 306 may provide an unbiased check on the performance of a machine learning model 310 after initial training (step 350). Further, validation data 306 may be used to fine tune a machine learning model's 310 hyperparameters (step 358). Initial training (step 350) does not utilize validation data 306, which helps prevent overfitting and ensures that the machine learning model 310 can generalize on unseen data. Further, validation data 306 allows for smaller adjustments (e.g., fine tuning, step 358) to a machine learning model 310 before final evaluation (step 360).

Testing data 308 is data which may be a subset of historical database 300. In one or more embodiments, until evaluation (step 360) machine learning model 310 has not previously had access to and/or been provided with testing data 308. Thus, testing data 308 may provide an additional and/or final unbiased check on the performance of machine learning model 310 after initial training (step 350) and fine tuning (step 358). Testing data 308 may be used to ensure that the machine learning model 310 may have the ability to generalize to new and/or unseen input data, and that the machine learning model 310 is not overfit to the training data 304 (and/or validation data 306). As machine learning model 310 has not been trained on testing data 308, testing data 308 may be used for evaluation (step 360) by measuring the machine learning model's 310 ability to generate sufficiently acceptable generated output data 322 (e.g., satisfying one or more model evaluation criteria 316).

Machine learning model 310 is software which includes (or is otherwise associated with) the functions and model constraints 312 (e.g., structure, algorithm, weights, hyperparameters, parameters, properties, attributes, and/or other metadata) to enable a data generator 318 to create generated output data 322. A machine learning model 310 may be trained and tuned using one or more machine learning techniques that optimize the generated output data 322 to have similar properties to existing data (e.g., historical data) of the same type. Non-limiting examples of model types for a machine learning model 310 include any type of neural network (NN) (e.g., multi-layer perceptron model, convolutional (CNN), recurrent (RNN), feed forward, modular, radial basis, liquid state, residual, etc.), decision tree, regression tree, Gaussian process regression (GPR) model, hidden Markov model, Naive Bayes classifier, support vector machine (SVM), k-nearest neighbor (KNN) model, and/or combination thereof.

Model constraint(s) 312 is data that may define one or more properties of a machine learning model 310. Model constraint(s) 312 may be divided into one or more logical types of data, including:
i. model type (e.g., neural network, decision tree, hidden Markov model, etc.);
ii. model hyperparameters (e.g., number of layers, types of layers, number of artificial neurons per layer, activation function types, weight range bounds, etc.); and
iii. model parameters (e.g., weights 425, centroids, physics informed constraints, imitation constraints, cycle loss constraints, etc.).

In one or more embodiments, model type may be further defined into sub-types with any level of detail. As a non-limiting example, a model type may be “physics informed” (e.g., as a “neural network”), where known physical and/or mathematical properties are defined such that generated output data 322 is optimized to satisfy the known physical and/or mathematical properties. As another non-limiting example, a “neural network” may be further defined as a convolutional neural network (CNN), recurrent neural network (RNN), and a feed forward neural network.

In one or more embodiments, non-limiting examples of model hyperparameters include:
i. Split ratio of how to divide existing data (e.g., historical database 300) into training data 304, validation data 306, and testing data 308 (e.g., the percentage of allotted to each type);
ii. Optimization/minimization algorithm(s) to use when training machine learning model 310 (e.g., gradient descent, stochastic gradient descent (SDG), genetic, root mean square propagation (RMSprop), Newton's method, etc.)
iii. Number (quantity) of epochs for training (i.e., iterations used to train using training data 304 and/or validation data 306).

Model trainer 314 is software that may be used to train machine learning model 310 using one or more model constraint(s) 312 and/or model evaluation criteria 316. In one or more embodiments, model trainer 314 may train a machine learning model 310 by iteratively adjusting values of the hyperparameters of the machine learning model 310. As a non-limiting example, model trainer may use a data generator 318 to process input data, using machine learning model 310, to create generated output data 322. Then the generated output data 322 is evaluated via one or more means (e.g., using model evaluation criteria 316), depending on the type of training. Non-limiting examples of evaluating generated output data 322 include (i) comparison to existing output data (e.g., “correct”, “tagged” data), (ii) scoring (e.g., “grading”) by a human and/or another software instance, (iii) threshold determination based on a combination of multiple outputs (number/percent of false positives, number/percent of false negatives). Then, based on the evaluation, model trainer 314 may further modify one or more properties of the machine learning model 310 to produce generated output data 322 that better satisfies the model constraint(s) 312 (e.g., via gradient descent of individual constraints, minimization of sum of constraint differential total, etc.).

Model evaluation criteria 316 is data which is used to evaluate (e.g., grade, score, etc.) the general performance, effectiveness, and/or correctness of a machine learning model 310 (e.g., by model trainer 314). Model evaluation criteria 316 may include one or more threshold(s) which may be used to determine when training of a machine learning model 310 may be stopped (e.g., one or more testing threshold(s) when training using training data 304, one or more validation threshold(s) when training using validation data 306, and one or more final evaluation threshold(s) when evaluating a machine learning model 310 during evaluation (step 360) using testing data 308). Further, model evaluation criteria 316 may include one or more evaluation function(s) used to objectively measure the performance of a machine learning model 310. Non-limiting examples of evaluation functions include:
i. Accuracy, which may be calculated using coefficient of determination (R2), mean absolute percentage error (MAPE), mean squared error (MSE), and/or mean squared deviation (MSD);
ii. Precision, which may be calculated using standard deviation of relative error;
iii. Robustness, which may be calculated using root mean square error (RMSE), root mean square deviation (RMSD), and/or coefficient of determination (R2); and/or
iv. Skew, which may be calculated using mean relative error and/or median relative error.

In step 350, model trainer 314 trains machine learning model 310 initially using training data 304. In one or more embodiments, initial training of machine learning model 310 uses training data 304, independently of validation data 306 and testing data 308. Additional details regarding the process of step 350 may be found in the description of steps 352, 354, and 356 in FIG. 3B.

In step 358, model trainer 314 fine tunes machine learning model 310 using validation data 306. In one or more embodiments, fine tuning of machine learning model 310 uses validation data 306, independently of training data 304 and testing data 308. In one or more embodiments, fine tuning machine learning model 310 (using validation data 306) may be substantially similar to training machine learning model 310 (using training data 304, as described in step 350), except that the adjustments made to the parameters of machine learning model 310 are smaller (in magnitude) for each iteration compared to the adjustments made to the parameters for each iteration during initial training (step 350).

In step 360, model trainer 314 evaluates the machine learning model 310 using testing data 308. In one or more embodiments, evaluation of the machine learning model 310 involves analyzing the machine learning model 310 using model evaluation criteria 316. Any combination of model evaluation criteria 316 may be used for the evaluation of a machine learning model 310 (e.g., accuracy may be the only criteria, a combination of accuracy and precision may be used, precision may be given a greater weight (made more important), etc.).

### —FIG. 3B—

FIG. 3B is a diagram of a process for training a machine learning model.

In one or more embodiments, training data 304 (and/or validation data 306) may be divided into two subsets based on the desired input and outputs of the machine learning model 310 being trained. As shown in FIG. 3B, training data 304 is divided into training input data 304I and training output data 304O.

Consider a scenario where training data 304 includes images of cats, dogs, and rabbits. Further, each image is “tagged” (i.e., with metadata) to indicate the contents of the associated image. Accordingly, each image is tagged with the string “cat”, “dog”, or “rabbit”. With such training data 304, a machine learning model 310 may be trained to “classify” the animal in a given image by attempting to generate the tag associated with the image. In such a scenario, the images (without tags) would be designated as the training input data 304I, while the associated tag for each image would be designated as the training output data 304O.

Generated output data 322 is data, generated by data generator 318, using machine learning model 310 and some input data (training input data 304I, in the example of FIG. 3B). In one or more embodiments, generated output data 322 is the data produced by a machine learning model 310 after processing the input data. In one or more embodiments, generated output data 322 is the final stage of the network's forward pass. Depending on the task, the generated output data 322 could take various forms. As a non-limiting example, in a classification task, the generated output data 322 could be the probabilities of each class; in a regression task, the generated output data 322 could be a single continuous value; in a generative model, the generated output data 322 could be an entirely new data instance similar to the training input data 304I.

In step 352, for an initial iteration, model trainer 314 creates machine learning model 310 per the requirements of model constraints 312. Upon initial creation, machine learning model 310 may include arbitrary and/or default parameter values (e.g., weights equal to 1, random weights).

For any subsequent iteration (at step 352), model trainer 314 tunes machine learning model 310, while complying with model constraints 312. Specifically, in one or more embodiments, model trainer 314 may adjust the parameters of a machine learning model 310 (e.g., the weights 425 of the artificial neurons 418 in an artificial neural network 410). One or more techniques (e.g., gradient descent) may be utilized for optimizing the desired result of the generated output data 322 when modifying the parameters of a machine learning model 310 (e.g., as specified by model constraints 312).

In step 354, the data generator 318 uses the updated (or newly created) machine learning model 310 to process some (or all) of training input data 304I to generate generated output data 322. In the example of classifying images to type of animals, training input data 304I includes images of cats, dogs, and rabbits without any of the associated tags (training output data 304O). Accordingly, at (2), the data generator 318 processes one or more of the images (from training input data 304I) using the machine learning model 310 to generate one or more corresponding tags for each image (as generated output data 322). The particular and specific structure, weights, and functions of the machine learning model 310 dictate the content of generated output data 322.

In one or more embodiments, a machine learning model 310 that is newly created or completely untrained would expect to generate outputs (i.e., generated output data 322) that are (seemingly) random. In the first iteration, the machine learning model 310 has not yet received any feedback on results and therefore cannot produce any output that is “learned”.

In step 356, model trainer 314 evaluates generated output data 322 by comparing generated output data 322 to training output data 304O. That is, as training output data 304O includes the correct tags for each image (“cat”, “dog”, “rabbit”) model trainer is therefore able to determine the correctness of each tag created in the generated output data 322 and calculate an overall correctness of the machine learning model 310. As a non-limiting example, if 100 tags were created in generated output data 322, and 65 of those tags matched the tag in training output data 304O (for the same associated image), machine learning model 310 may be given a calculated correctness score of “65%” (65/100=0.65). In any embodiment, model trainer 314 may use model evaluation criteria 316 when evaluating a machine learning model 310.

Further, the model trainer 314 uses model evaluation criteria 316 to make a determination if machine learning model 310 is sufficiently trained to stop the training process; or, if not sufficiently trained, to continue modifying the machine learning model 310. In one or more embodiments, model evaluation criteria 316 may include a minimum threshold which must be surpassed in order for training of the machine learning model to stop. As a non-limiting example, model evaluation criteria 316 may specify that the machine learning model 310 must be (at least) 98% accurate before training stops.

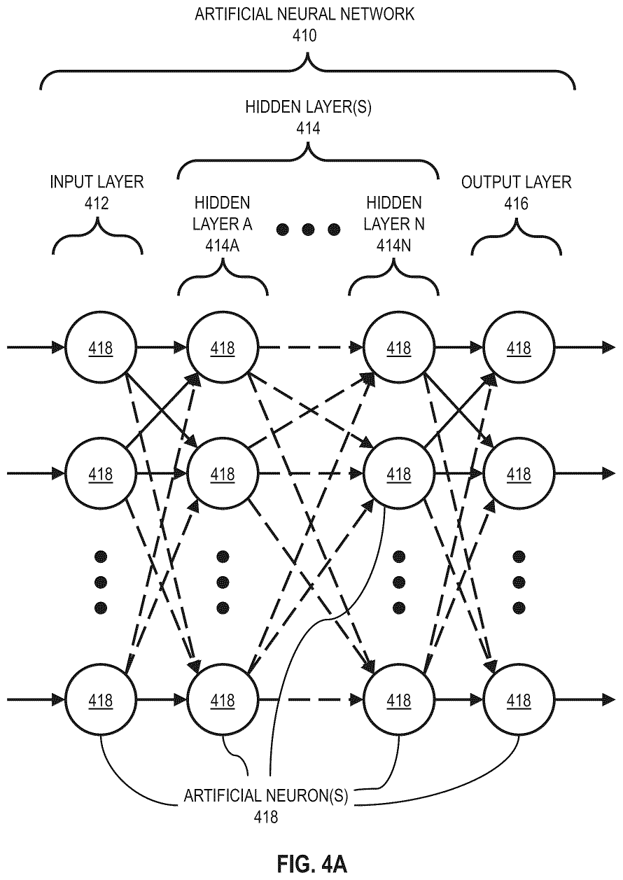

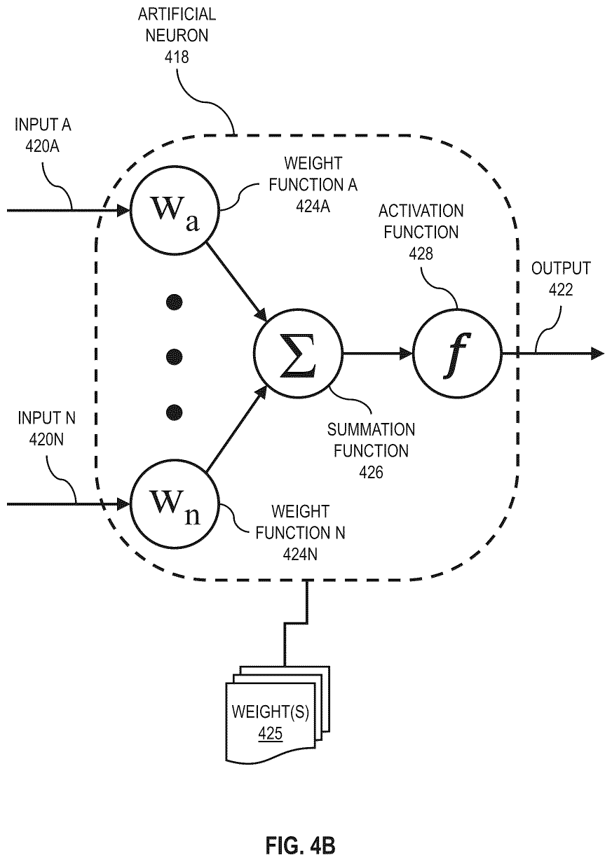

### —FIGS. 4A-4B—

FIG. 4A is a diagram of an artificial neural network. FIG. 4B is a diagram of an artificial neuron.

An artificial neural network 410 is a type of machine learning model 310. In one or more embodiments, artificial neural network 410 includes an input layer 412, an output layer 416, and may include one or more hidden layer(s) 414 (e.g., hidden layer A 414A, hidden layer N 414N) disposed between the input layer 412 and the output layer 416. In turn, each layer (input layer 412, hidden layer(s) 414, output layer 416) includes one or more artificial neuron(s) 418. The output 422 of each artificial neuron 418 of one layer may “connect” to an input 420 of each artificial neuron of the next layer. As a non-limiting example, as shown in FIG. 4A, the output 422 of each artificial neuron 418 of the input layer 412 is connected to the input 420 of each artificial neuron 418 of the hidden layer A 414A.

A layer (e.g., input layer 412, hidden layer(s) 414, output layer 416), generally, is a logical association of one or more artificial neuron(s) 418. Artificial neurons 418 within a layer may operate independently (of other artificial neurons 418) within the layer. In one or more embodiments, each artificial neuron 418 in a layer receives one or more data as one or more input(s) 420, respectively, processes the data in the artificial neuron 418 to generate a single output 422, then passes that output 422 to each artificial neuron 418 of the next layer. That is, artificial neurons 418 do not receive data from other artificial neurons 418 from within the same layer, and conversely, artificial neurons 418 do not send data to other artificial neurons 418 within the same layer. Thus, artificial neurons 418, within the same layer, may operate in parallel, and are only “connected” to artificial neurons 418 in neighboring layers (however, artificial neurons 418 of input layer 412 receive inputs 420 from outside artificial neural network 410, and artificial neurons 418 of output layer 416 send outputs 422 outside of artificial neural network 410).

Input layer 412 is a layer in an artificial neural network 410. In one or more embodiments, input layer 412 is the initial layer that interacts directly with the data provided for learning or prediction. The input layer 412 is responsible for receiving and normalizing the raw input data and passing the input data on to the subsequent layers (e.g., hidden layers 414, output layer 416) for further processing. Each artificial neuron 418 in the input layer 412 represents a single feature or attribute of the data, such as a pixel in an image, or a word in a text document. The number of artificial neurons 418 in the input layer 412 typically corresponds to the dimensionality of the input data. As a non-limiting example, in an artificial neural network 410 designed to process images of size 28×28 pixels, the input layer would have 784 artificial neurons 418 (e.g., 28×28=784). The artificial neurons 418 in the input layer 412 may perform no computation, but rather serve as a gateway for data to enter an artificial neural network 410.

Hidden layer 414 is a layer in an artificial neural network 410. In one or more embodiments, hidden layers 414 are the layers between the input layer 412 and output layer 416. Hidden layers 414 may be termed “hidden” because their values are not directly observable from the artificial neural network's 410 input or output. Each artificial neuron 418 in a hidden layer 414 may represent a learned abstract feature, which is a combination of the input features. Hidden layers 414 may perform the bulk of the computation involved in transforming the input data into the output data. The artificial neurons 418 in the hidden layers 414 apply a set of weights 425 to the inputs 420 and pass the result through a summation function 426 and an activation function 428, which introduces non-linearity into the model. Consequently, an artificial neural network 410 may “learn” complex patterns and relationships in the data. The number of hidden layers 414 and the number of artificial neurons 418 in each hidden layer 414 are key parameters of the network architecture (e.g., model constraints 312) and may have a significant impact on an artificial neural network's 410 performance (e.g., the results of evaluation).

Output layer 416 is a layer in an artificial neural network 410. In one or more embodiments, an output layer 416 of an artificial neural network 410 is the final layer that produces the results or predictions from the input data processed through the hidden layers 414. Each artificial neuron 418 in the output layer 416 corresponds to a possible output of the model. As a non-limiting example, in a binary classification problem, there would be two artificial neurons 418 representing the two classes (e.g., “cat” and “dog”). The values in the output layer 416 are computed from the values in the preceding hidden layer 414, with each artificial neuron 418 applying a set of weights 425 and an activation function 428. In one or more embodiments, the activation function 428 used in the artificial neurons 418 of the output layer 416 depends on the nature of the input data and the model constraints 312 used to train the artificial neural network 410. For example, a “SoftMax” activation function 428 is often used for multi-class classification problems as it provides a probability distribution over the classes, while a sigmoid function is used for binary classification problems.

Generally, for an artificial neural network 410, data is passed as inputs (e.g., input data) to the input layer 412 of the artificial neural network 410. Specifically, in one or more embodiments, input data may be parsed into smaller portions, where the smaller portions of the input data are provided to different artificial neurons 418 of the input layer 412. In turn, the input data (and/or some portion thereof) is then processed by each artificial neuron 418 of the input layer 412, respectively, before being passed to the first hidden layer 414 (e.g., hidden layer A 414A). Similarly, the output 422 of each artificial neuron 418 of the first hidden layer 414 is then passed to an input 420 of each artificial neuron 418 of the next layer (e.g., another hidden layer 414, output layer 416). The data continues to cascade through the artificial neural network 410 until processed by the artificial neuron(s) 418 of the output layer 416 and sent out of the artificial neural network 410.

Artificial neuron 418 is software which includes (or is otherwise associated with) one or more weight function(s) 424, a summation function 426, and an activation function 428. In one or more embodiments, an artificial neuron 418 may include (or otherwise be associated with) one or more weight values that respectively correspond to each weight function 424. Further, an artificial neuron 418 may include (or otherwise be associated with) a function type associated with the activation function.

Weight function 424 is a mathematical operation that multiplies an input 420 with a weight value. In one or more embodiments, an artificial neuron 418 includes a weight function 424 assigned to each input 420 of the artificial neuron 418 (e.g., input A 420A is used for weight function A 424A). Thus, each input 420 to an artificial neuron 418 may be multiplied by a different weight value. As a non-limiting example, if input A is equal to “5” and weight A 425A is equal to “0.6”, weight function 424 would multiply 5 by 0.6 to calculate “3”.

Weight 425 is data used to modify an input 420 to an artificial neuron 418. In one or more embodiments, a weight 425 represents the strength or influence of a particular input 420 on the output 422. A weight 425 may be a numerical value that is multiplied with the input 420 before being passed to the summation function 426 and activation function 428. During the training process, weights 425 are adjusted to minimize the difference between the artificial neural network's 410 generated output data 322 and the training output data 304O. That is, as a non-limiting example, an artificial neural network 410 is trained to find the optimal set of weights 425 that allows the artificial neural network 410 to accurately model the underlying patterns in the data.

Summation function 426 is a mathematical operation which sums the output of each weight function 424 into a single value. In one or more embodiments, the combined sum of the output of each weight function 424 may be referred to as a “weighted sum” which represents the combined influence of all the inputs on the artificial neuron's 418 output.

Activation function 428 is a mathematical operation which calculates the output 422 of an artificial neuron 418. In one or more embodiments, an activation function 428 takes the weighted sum of the inputs (the output of summation function 426) and transforms it into an output 422 that is passed on to the next layer. An activation function 428 may introduce non-linearity into an artificial neural network 410, allowing the artificial neural network 410 to learn complex patterns and relationships from the training data 304. Non-limiting examples of an activation function 428 include the sigmoid, hyperbolic tangent (tan h), rectified linear unit (ReLU), leaky ReLU, and SoftMax functions. The transformation caused by an activation function 428 can limit the output to a certain range (like between 0 and 1 for the sigmoid function) or introduce sparsity in the network (like the ReLU function which outputs zero for all negative inputs).

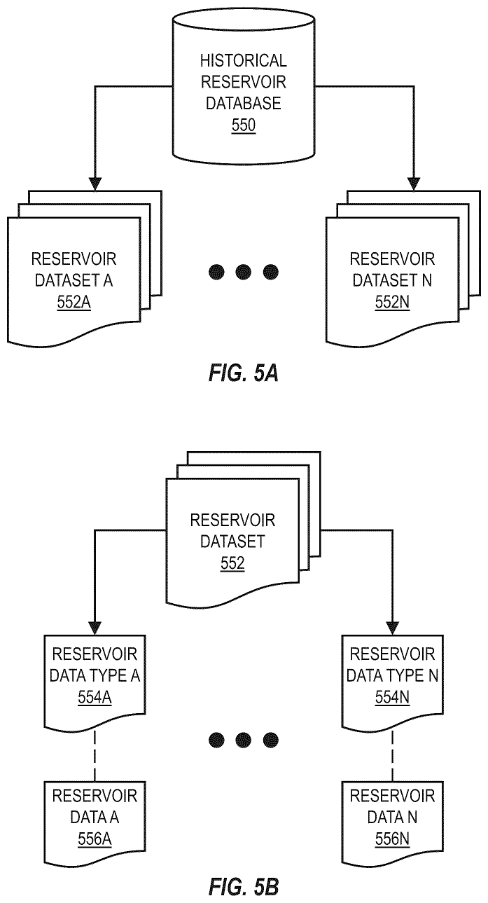

### —FIGS. 5A-5B—

FIG. 5A is a diagram of a historical borehole database and corresponding reservoir datasets. FIG. 5B is a diagram of a reservoir dataset and corresponding reservoir data types.

Historical reservoir database 550 is a collection of one or more reservoir dataset(s) 552. In one or more embodiments, historical reservoir database 550 may act as a historical database 300 for use when training one or more machine learning model(s) 310. In any embodiment, historical reservoir database 550 may be stored on one information handling system 201 or across multiple information handling systems 201 (e.g., in a virtual storage volume).

Reservoir dataset 552 (e.g., reservoir dataset A 552A, reservoir dataset N 552N). In one or more embodiments, reservoir dataset 552 may be associated with a single borehole (e.g., borehole 116) and/or single reservoir. Further, reservoir dataset 552 includes one or more reservoir data 556 (e.g., data A 556A, data N 556N) that may each be associated with a reservoir data type 554 (e.g., reservoir data type A 554A, reservoir data type N 554N).

Reservoir data type 554 is a property (i.e., metadata) that may be associated with one or more reservoir data 556, where reservoir data 556 includes the underlying digital information. As a non-limiting example, a reservoir data type 554 may be “soil properties” and the associated reservoir data 556 may be the actual data (e.g., numerical values, string descriptions, etc.) related to the properties of the soil in and around the borehole 116 associated with reservoir dataset 552. As another non-limiting example, a reservoir data type 554 may be “location” and the associated reservoir data 556 may be the latitude and longitude coordinates of the location of the associated borehole 116.

Non-limiting examples of reservoir data types 554 (with corresponding reservoir data 556) include:
i. “reservoir rock features”, which may be associated with reservoir data 556 including: shape, depth isopach, resource type, top-of-zone, net pay thickness (q-H), clay type, clay volume, non-clay volume, density-porosity, bulk density, and gamma ray response;
ii. “reservoir fluid features”, which may be associated with reservoir data 556 including: water saturation, hydro-carbon pore volume, total organic carbon, resistivity, and effective porosity;
iii. “logging data”, which may be associated with reservoir data 556 including: neutron density logs, neutron porosity logs, sonic/acoustic logs, gamma ray logs, and resistivity logs;
iv. “well geometry features”, which may be associated with reservoir data 556 including: latitude, longitude, and altitude of the reservoir, lateral length, generic drainage, true vertical depth, azimuth grid north, upper perf, lower perf, perf interval, and toe angle;
v. “completion features”, which may be associated with reservoir data 556 including: fracturing stages, average stage spacing, total water pumped, total fluid pumped, water intensity, proppant intensity, proppant loading, proppant type, and date(s) of well construction; and
vi. “production features”, which may be associated with reservoir data 556 including: production rate, date(s) of resource production, and estimated ultimate recovery (EUR).

Reservoir data types 554 are not mutually exclusive. That is, a single set of reservoir data 556 may be categorized into (e.g., associated with) two or more reservoir data types 554.

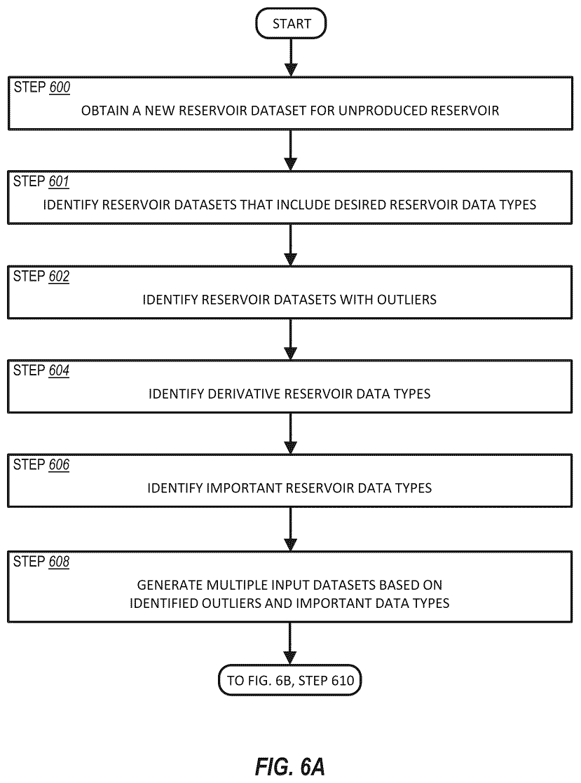

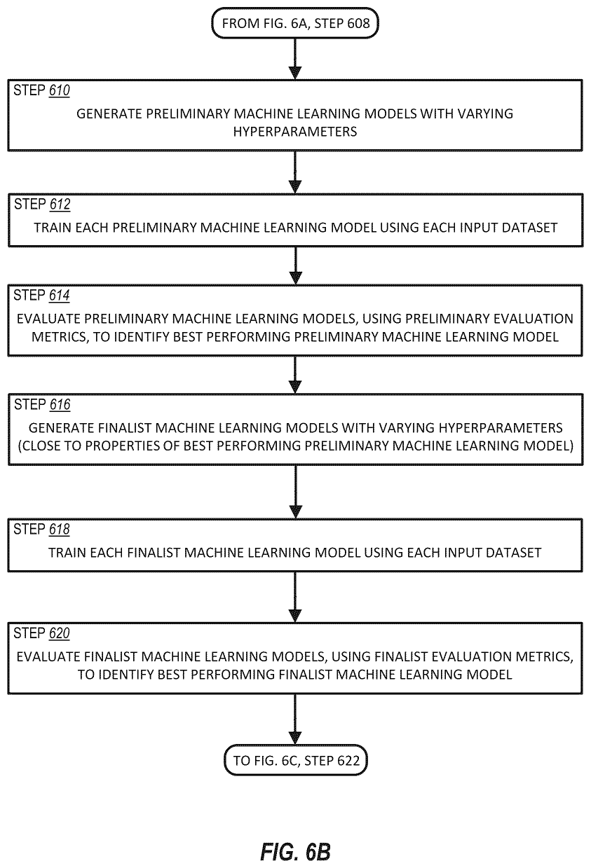

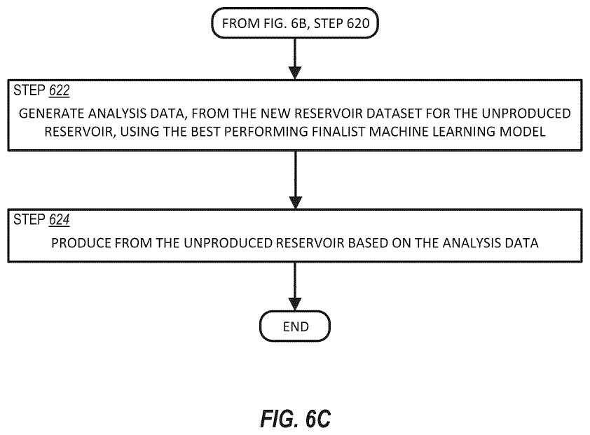

### —FIGS. 6A-6C—

FIG. 6A is a flowchart of a method for preparing datasets. FIG. 6B is a flowchart of a method for training machine learning models. FIG. 6C is a flowchart of a method for generating and using analysis data of a machine learning model. All or a portion of the methods shown may be performed by one or more components of information handling system 201 (see description in FIG. 2) or a user thereof. While the various steps in this flowchart are presented and described sequentially, a person of ordinary skill in the relevant art (having the benefit of this detailed description) would appreciate that some or all steps may be executed in different orders, combined, or omitted, and some or all steps may be executed in parallel.

In step 600, a new reservoir dataset 552 is obtained for an unproduced reservoir. In one or more embodiments, “well geometry”, “completion”, and “production” reservoir data types 554 may not be obtained as a borehole 116 for the unproduced reservoir may not be constructed yet. However, “reservoir rock”, “reservoir fluid”, and “logging data” may be measured, processed, collected, and/or otherwise made available for additional processing and analysis.

In step 601, historical reservoir database 550 is searched to one or more identify existing reservoir datasets 552 (e.g., reservoir dataset(s) 552 existing prior to initiation of step 600) that include one or more desired reservoir data type(s) 554. As a non-limiting example, a user may be interested in reservoir datasets 552 that include, at least, reservoir data types 554 for (i) location (latitude and longitude coordinates) within defined geographic region, (ii) water saturation within a certain range, and (iii) clay volume within a certain range. Accordingly, the user may query historical reservoir database 550 to identify all reservoir datasets 552 that include those desired reservoir data types 554 (and within the desired ranges).

In one or more embodiments, the desired reservoir data type(s) 554 may match reservoir data type(s) 554 available in the new reservoir dataset 552 for the unproduced reservoir. Accordingly, the desired reservoir data type(s) 554 from reservoir datasets 552 (from historical database 300) may be used (as inputs) to train a machine learning model to predict “production” reservoir data type(s) 554 (e.g., “analysis data” as outputs). Thus, given only the available reservoir data type(s) (e.g., “reservoir rock”, “reservoir fluid”, and “logging data”) of the unproduced reservoir, “production” data (e.g., “analysis data”) may be predicted using the trained model.

In step 602, reservoir datasets 552 that include outlier data may be identified. In one or more embodiments, certain boreholes may experience non-standard condition and procedures that are unrelated to the underlying physics of the borehole 116 and target reservoir. As a non-limiting example, construction of a well may have been paused for an extended period due to funding issues, legal issues, or market conditions. As another non-limiting example, boreholes 116 may have been drilled for purposes other than production (e.g., for storage). Further, any reservoir datasets 552 that includes a “null” value in reservoir data 556 associated with an important reservoir data type 554 (or during an important period of time) may also be identified. In one or more embodiments, inter quartile range (IQR) filtering may be used to identify outlier data.

In step 604, derivate reservoir data types are identified and/or direct measurement reservoir data types are identified. In one or more embodiments, certain reservoir data 556 may be generated mostly (or entirely) using other reservoir data 556 in a reservoir dataset 552. As a non-limiting example, a first reservoir data type 554 may exist based on the direct measurement of the mass of a formation, a second reservoir data type 554 may exist based on the direct measurement of the volume of the same formation, and a third reservoir data type 554 may be calculated (not directly measured) for the density of the same formation (dividing mass by volume). In such an example, the third reservoir data type 554 is not directly measured, but instead is a derivative of the underlying first and second reservoir data types 554.

In such cases, generated reservoir data 556 may not provide any additional insight into the borehole 116 and rather, may exist for human analysis. Accordingly, when training a machine learning model, such relationships between existing reservoir data types 554 may not be relevant (or may be independently discovered) by the model. Further, including such derivative reservoir data types 554 may provide too much weight to the underlying reservoir data 556 from which the generated reservoir data 556 was generated. Accordingly, identifying such reservoir data types 554 allows for potential filtering, if needed, to exclude derivative reservoir data types 554 (or include only direct measurement reservoir data types 554).

In step 606, important reservoir data types 554 are identified in reservoir datasets 552. In one or more embodiments, “important” reservoir data types 554 are reservoir data types 554 that have an effect on generated output data 322. That is, as a non-limiting example, an important reservoir data type 554 (when used as input data) may affect the value of generated output data 322 when processed by data generator 318. Conversely, unimportant reservoir data types 554 (when used as input data) may have no (or little) effect on the value of generated output data 322 (i.e., reservoir data types 554 that are “independent” of desired output data).

One or more techniques (and/or algorithms) may be employed to identify important (and/or unimportant) reservoir data types 554. Non-limiting examples of techniques which may be used to identify important (and/or unimportant) reservoir data types 554 include random forest regression (RFR), recursive feature elimination (RFE), and support vector regressions (SVR).

In step 608, multiple input datasets are generated to train machine learning models.

As a non-limiting example, a first input dataset may include all of the reservoir datasets 552 identified in step 601, with all of the reservoir datasets 552 identified in step 602 removed (i.e., removing reservoir datasets 552 with outlier reservoir data 556).

As another non-limiting example, a second input dataset may include reservoir datasets 552 (with outlier reservoir datasets 552 removed), and further excluding derivative reservoir data types 554 and corresponding reservoir data 556 in each of the reservoir datasets 552 (as identified in step 604).

As another non-limiting example, a third input dataset may include reservoir datasets 552 (with outlier reservoir datasets 552 removed), and further including only “important” reservoir data types 554 as identified by all three of the referenced methods in step 606 (i.e., including only reservoir data types 554 that each of RFR, RFE, and SVR identified as “important”).

As another non-limiting example, a fourth input dataset may include reservoir datasets 552 (with outlier reservoir datasets 552 removed), and further including only “important” reservoir data types 554 as identified by only two of the (three) referenced methods in step 606 (e.g., including only reservoir data types 554 that were identified as “important” by RFR and RFE, but not SVR).

One of ordinary skill in the art, provided the benefit of this detailed description, would understand that any combination of reservoir datasets 552 and varying exclusion of reservoir data types 554 (and corresponding reservoir data 556) therein may be used to generate an input dataset.

In step 610, preliminary machine learning models are generated. Preliminary machine learning models may be a of varying types (e.g., neural network, decision tree, hidden Markov model, etc.) with varying hyperparameters (e.g., number of layers, types of layers, nodes/neurons per layer, etc.) and varying properties (e.g., activation functions, activation thresholds, optimization metrics, etc.).

In step 612, each of the preliminary machine learning models is trained using one or more input dataset(s) as a historical database. In one or more embodiments, each of the input datasets generated at step 608 is used to train each of the preliminary machine learning models. Further, the preliminary machine learning models may not be trained fully. Rather, each preliminary machine learning model may be trained to a point where a determination may be made about the sufficiency of the preliminary machine learning model.

In step 614, each of the preliminary machine learning models are evaluated using preliminary evaluation metrics. In one or more embodiments, each preliminary machine learning model may be analyzed and evaluated to determine which of the preliminary machine learning models performs best using one or more metrics (i.e., a “best preliminary machine learning model”). In one or more embodiments, evaluation of the preliminary machine learning models may be based on model evaluation criteria 316.

In step 616, “finalist” machine learning models are generated with varying properties. In one or more embodiments, the finalist machine learning models have properties that are closer (bounded within ranges around) the properties of the best preliminary machine learning model(s). As a non-limiting example, if the best preliminary machine learning model was a neural network with (i) eight hidden layers, and (ii) a height (number of artificial neurons per layer) of 20, finalist machine learning models may be generated with six to ten (8±2) hidden layers, with heights varying from 15 to 25.

In step 618, each of the finalist machine learning models is trained using one or more input dataset(s) as a historical database. In one or more embodiments, each of the input datasets generated at step 608 is used to train each of the finalist machine learning models. In comparison to the preliminary machine learning models trained at step 612, each of the finalist machine learning models may be trained further (and/or fully) to allow for more accurate analysis of the final model.

In step 620, finalist machine learning models are evaluated using finalist evaluation metrics. In one or more embodiments, each finalist machine learning model may be analyzed and evaluated to determine and/or identify which of the finalist machine learning models performs best using one or more metrics (i.e., a “best finalist machine learning model”). In one or more embodiments, evaluation of the finalist machine learning models may be based on model evaluation criteria 316.

In step 622, analysis data is generated using the best finalist machine learning model (as identified in step 620). In one or more embodiments, the new reservoir dataset (e.g., of an unproduced reservoir) may be provided to the best finalist machine learning model to generate the desired analysis (e.g., EUR for the given reservoir).

In step 624, depending on the analysis data generated, a borehole 116 may be modified (e.g., drilled further) to access and produce from a reservoir. In one or more embodiments, analysis data may allow for speedier identification and production from well. Conversely, based on the analysis data provided, less (or no further) action may be taken on a given borehole 116 to access a reservoir.

### Solutions and Improvements

The methods and systems described above are an improvement over the current technology as the methods and systems described herein provide machine learning regression algorithms to predict EUR with increased accuracy, precision, and robustness. Provided with sufficient computing power and sufficient historical data of reservoirs with overlapping properties, the inherent complexity of unconventional reservoirs may be accounted for, without time consuming and bespoke modeling required using conventional techniques.

Further, such modeling may be automated and include, as a preliminary or intermediary step, training machine learning models to identify and account for properties of greatest criticality to prediction. Thus, such machine learning processes may be automated, identify most relevant properties, and provide more consistent, accurate, and precise predictions of EUR.

### Statements

The systems and methods may comprise any of the various features disclosed herein, comprising one or more of the following statements.

Statement 1. A method for analyzing an unproduced reservoir, comprising obtaining a new reservoir dataset, for the unproduced reservoir, that comprises a plurality of desired reservoir data types identifying a plurality of existing reservoir datasets, in a historical reservoir database wherein each reservoir dataset, of the plurality of existing reservoir datasets, comprises a desired reservoir data type of the plurality of desired reservoir data types training a plurality of finalist machine learning models using the plurality of existing reservoir datasets identifying a best finalist machine learning model of the plurality of finalist machine learning models; processing the new reservoir dataset, using best finalist machine learning model, to generate analysis data for the unproduced reservoir.

Statement 2. The method of statement 1, wherein the plurality of desired reservoir data types comprises reservoir rock features reservoir fluid features; or

Statement completion features.

Statement 3. The method of statements 1-2, wherein the finalist machine learning models are each a multi-layer perceptron model.

Statement 4. The method of statements 1-3, wherein the analysis data is an estimated ultimate recovery (EUR) for the unproduced reservoir.

Statement 5. The method of statements 1-4, wherein identifying the plurality of existing reservoir datasets comprises identifying outlier reservoir datasets in the plurality of existing reservoir datasets; generating a first input dataset by removing the outlier reservoir datasets from the plurality of existing reservoir datasets.

Statement 6. The method of statement 5, wherein identifying the plurality of existing reservoir datasets further comprises identifying derivate reservoir data types; generating a second input dataset by removing the derivate reservoir data types from the plurality of existing reservoir datasets.

Statement 7. The method of statement 6, wherein identifying the plurality of existing reservoir datasets further comprises identifying unimportant reservoir data types; generating a third input dataset by removing the unimportant reservoir data types from the plurality of existing reservoir datasets.

Statement 8. The method of statement 7, wherein identifying the unimportant reservoir data types comprises using random forest regression (RFR), recursive feature elimination (RFE), or support vector regressions (SVR).

Statement 9. The method of statement 8, wherein training the plurality of finalist machine learning models comprises training each of the plurality of finalist machine learning models using a plurality of input datasets wherein the plurality of input datasets comprises the first input dataset, the second input dataset, and the third input dataset.

Statement 10. The method of statement 9, wherein prior to training the plurality of finalist machine learning models, the method further comprises training a plurality of preliminary machine learning models using the plurality of input datasets.

Statement 11. The method of statement 10, wherein after training the plurality of preliminary machine learning models, the method further comprises identifying a best preliminary machine learning model of the plurality of preliminary machine learning models.

Statement 12. The method of statement 11, wherein after identifying the best preliminary machine learning model, the method further comprises generating the plurality of finalist machine learning models based on the best preliminary machine learning model.

Statement 13. An information handling system, comprising memory; a processor, wherein the processor is configured execute a method for analyzing an unproduced reservoir, comprising obtaining a new reservoir dataset, for the unproduced reservoir, that comprises a plurality of desired reservoir data types identifying a plurality of existing reservoir datasets, in a historical reservoir database wherein each reservoir dataset, of the plurality of existing reservoir datasets, comprises a desired reservoir data type of the plurality of desired reservoir data types training a plurality of finalist machine learning models using the plurality of existing reservoir datasets identifying a best finalist machine learning model of the plurality of finalist machine learning models; processing the new reservoir dataset, using best finalist machine learning model, to generate analysis data for the unproduced reservoir.

Statement 14. The information handling system of statement 13, wherein the plurality of desired reservoir data types comprises reservoir rock features reservoir fluid features; or statement completion features.

Statement 15. The information handling system of statements 13-14, wherein the finalist machine learning models are each a multi-layer perceptron model.

Statement 16. The information handling system of statements 13-15, wherein the analysis data is an estimated ultimate recovery (EUR) for the unproduced reservoir.

Statement 17. The information handling system of statements 13-16, wherein identifying the plurality of existing reservoir datasets comprises identifying outlier reservoir datasets in the plurality of existing reservoir datasets; generating a first input dataset by removing the outlier reservoir datasets from the plurality of existing reservoir datasets.

Statement 18. The information handling system of statements 13-17, wherein identifying the plurality of existing reservoir datasets further comprises identifying derivate reservoir data types; generating a second input dataset by removing the derivate reservoir data types from the plurality of existing reservoir datasets.

Statement 19. The information handling system of statement 18, wherein identifying the plurality of existing reservoir datasets further comprises identifying unimportant reservoir data types using random forest regression (RFR), recursive feature elimination (RFE), or support vector regressions (SVR); generating a third input dataset by removing the unimportant reservoir data types from the plurality of existing reservoir datasets.

Statement 20. The information handling system of statement 19, wherein training the plurality of finalist machine learning models comprises training each of the plurality of finalist machine learning models using a plurality of input datasets wherein the plurality of input datasets comprises the first input dataset, the second input dataset, and the third input dataset.

### General Notes

As it is impracticable to disclose every conceivable embodiment of the technology described herein, the figures, examples, and description provided herein disclose only a limited number of potential embodiments. A person of ordinary skill in the relevant art would appreciate that any number of potential variations or modifications may be made to the explicitly disclosed embodiments, and that such alternative embodiments remain within the scope of the broader technology. Accordingly, the scope should be limited only by the attached claims. Further, the compositions and methods are described in terms of “comprising,” “containing,” or “including” various components or steps, the compositions and methods may also “consist essentially of” or “consist of” the various components and steps. Moreover, the indefinite articles “a” or “an,” as used in the claims, are defined herein to mean one or more than one of the elements that it introduces. Certain technical details, known to those of ordinary skill in the relevant art, may be omitted for brevity and to avoid cluttering the description of the novel aspects.

For further brevity, descriptions of similarly named components may be omitted if a description of that similarly named component exists elsewhere in the application. Accordingly, any component described with respect to a specific figure may be equivalent to one or more similarly named components shown or described in any other figure, and each component incorporates the description of every similarly named component provided in the application (unless explicitly noted otherwise). A description of any component is to be interpreted as an optional embodiment-which may be implemented in addition to, in conjunction with, or in place of an embodiment of a similarly-named component described for any other figure.

### LEXICOGRAPHICAL NOTES

As used herein, adjective ordinal numbers (e.g., first, second, third, etc.) are used to distinguish between elements and do not create any ordering of the elements. As an example, a “first element” is distinct from a “second element”, but the “first element” may come after (or before) the “second element” in an ordering of elements. Accordingly, an order of elements exists only if ordered terminology is expressly provided (e.g., “before”, “between”, “after”, etc.) or a type of “order” is expressly provided (e.g., “chronological”, “alphabetical”, “by size”, etc.). Further, use of ordinal numbers does not preclude the existence of other elements. As an example, a “table with a first leg and a second leg” is any table with two or more legs (e.g., two legs, five legs, thirteen legs, etc.). A maximum quantity of elements exists only if express language is used to limit the upper bound (e.g., “two or fewer”, “exactly five”, “nine to twenty”, etc.). Similarly, singular use of an ordinal number does not imply the existence of another element. As an example, a “first threshold” may be the only threshold and therefore does not necessitate the existence of a “second threshold”.

As used herein, the word “data” may be used as an “uncountable” singular noun—not as the plural form of the singular noun “datum”. Accordingly, throughout the application, “data” is generally paired with a singular verb (e.g., “the data is modified”). However, “data” is not redefined to mean a single bit of digital information. Rather, as used herein, “data” means any one or more bit(s) of digital information that are grouped together (physically or logically). Further, “data” may be used as a plural noun if context provides the existence of multiple “data” (e.g., “the two data are combined”).

As used herein, the term “operative connection” (or “operatively connected”) means the direct or indirect connection between devices that allows for the transmission of data. For example, the phrase ‘operatively connected’ may refer to a direct connection (e.g., a direct wired or wireless connection between devices) or an indirect connection (e.g., multiple wired and/or wireless connections between any number of other devices connecting the operatively connected devices).

As used herein, indefinite articles “a” and “an” mean “one or more”. That is, the explicit recitation of “an” element does not preclude the existence of a second element, a third element, etc. Further, definite articles (e.g., “the”, “said”) mean “any one of” (the “one or more” elements) when referring to previously introduced element(s). As an example, there may exist “a processor”, where such a recitation does not preclude the existence of any number of other processors. Further, “the processor receives data, and the processor processes data” means “any one of the one or more processors receives data” and “any one of the one or more processors processes data”. It is not required that the same processor both (i) receive data and (ii) process data. Rather, each of the steps (“receive” and “process”) may be performed by different processors.

What is claimed is:

1. A method for analyzing an unproduced reservoir, comprising:
obtaining a new reservoir dataset, for the unproduced reservoir, that comprises a plurality of desired reservoir data types;
identifying a plurality of existing reservoir datasets, in a historical reservoir database,
wherein each reservoir dataset, of the plurality of existing reservoir datasets, comprises a desired reservoir data type of the plurality of desired reservoir data types;
training a plurality of finalist machine learning models using the plurality of existing reservoir datasets;
identifying a best finalist machine learning model of the plurality of finalist machine learning models; and
processing the new reservoir dataset, using best finalist machine learning model, to generate analysis data for the unproduced reservoir.

2. The method of claim 1, wherein the plurality of desired reservoir data types comprises:
reservoir rock features;
reservoir fluid features; or
completion features.

3. The method of claim 1, wherein the finalist machine learning models are each a multi-layer perceptron model.

4. The method of claim 1, wherein the analysis data is an estimated ultimate recovery (EUR) for the unproduced reservoir.

5. The method of claim 1, wherein identifying the plurality of existing reservoir datasets comprises:
identifying outlier reservoir datasets in the plurality of existing reservoir datasets; and
generating a first input dataset by removing the outlier reservoir datasets from the plurality of existing reservoir datasets.

6. The method of claim 5, wherein identifying the plurality of existing reservoir datasets further comprises:
identifying derivate reservoir data types; and
generating a second input dataset by removing the derivate reservoir data types from the plurality of existing reservoir datasets.

7. The method of claim 6, wherein identifying the plurality of existing reservoir datasets further comprises:
identifying unimportant reservoir data types; and
generating a third input dataset by removing the unimportant reservoir data types from the plurality of existing reservoir datasets.

8. The method of claim 7, wherein identifying the unimportant reservoir data types comprises:
using random forest regression (RFR), recursive feature elimination (RFE), or support vector regressions (SVR).

9. The method of claim 8, wherein training the plurality of finalist machine learning models comprises:
training each of the plurality of finalist machine learning models using a plurality of input datasets,
wherein the plurality of input datasets comprises the first input dataset, the second input dataset, and the third input dataset.

10. The method of claim 9, wherein prior to training the plurality of finalist machine learning models, the method further comprises:
training a plurality of preliminary machine learning models using the plurality of input datasets.

11. The method of claim 10, wherein after training the plurality of preliminary machine learning models, the method further comprises:
identifying a best preliminary machine learning model of the plurality of preliminary machine learning models.

12. The method of claim 11, wherein after identifying the best preliminary machine learning model, the method further comprises:
generating the plurality of finalist machine learning models based on the best preliminary machine learning model.

13. An information handling system, comprising:
memory; and
a processor, wherein the processor is configured execute a method for analyzing an unproduced reservoir, comprising:
obtaining a new reservoir dataset, for the unproduced reservoir, that comprises a plurality of desired reservoir data types;
identifying a plurality of existing reservoir datasets, in a historical reservoir database,
wherein each reservoir dataset, of the plurality of existing reservoir datasets, comprises a desired reservoir data type of the plurality of desired reservoir data types;
training a plurality of finalist machine learning models using the plurality of existing reservoir datasets;
identifying a best finalist machine learning model of the plurality of finalist machine learning models; and
processing the new reservoir dataset, using best finalist machine learning model, to generate analysis data for the unproduced reservoir.

14. The information handling system of claim 13, wherein the plurality of desired reservoir data types comprises:
reservoir rock features;
reservoir fluid features; or
completion features.

15. The information handling system of claim 13, wherein the finalist machine learning models are each a multi-layer perceptron model.

16. The information handling system of claim 13, wherein the analysis data is an estimated ultimate recovery (EUR) for the unproduced reservoir.

17. The information handling system of claim 13, wherein identifying the plurality of existing reservoir datasets comprises:
identifying outlier reservoir datasets in the plurality of existing reservoir datasets; and
generating a first input dataset by removing the outlier reservoir datasets from the plurality of existing reservoir datasets.

18. The information handling system of claim 17, wherein identifying the plurality of existing reservoir datasets further comprises:
identifying derivate reservoir data types; and
generating a second input dataset by removing the derivate reservoir data types from the plurality of existing reservoir datasets.

19. The information handling system of claim 18, wherein identifying the plurality of existing reservoir datasets further comprises:
identifying unimportant reservoir data types using random forest regression (RFR), recursive feature elimination (RFE), or support vector regressions (SVR); and
generating a third input dataset by removing the unimportant reservoir data types from the plurality of existing reservoir datasets.

20. The information handling system of claim 19, wherein training the plurality of finalist machine learning models comprises:
training each of the plurality of finalist machine learning models using a plurality of input datasets,
wherein the plurality of input datasets comprises the first input dataset, the second input dataset, and the third input dataset.
